(19) United States
(12) Patent Application Publication
(10) Pub. No.: US 2024/0327674 A1
(43) Pub. Date: Oct. 3, 2024

(54) POLISHING COMPOSITION, POLISHING METHOD, AND METHOD FOR PRODUCING SEMICONDUCTOR SUBSTRATE

(71) Applicant: FUJIMI INCORPORATED, Kiyosu-shi (JP)

(72) Inventors: Ryota MAE, Kiyosu-shi (JP); Akane KUMAYAMA, Kiyosu-shi (JP)

(73) Assignee: FUJIMI INCORPORATED, Kiyosu-shi (JP)

(21) Appl. No.: 18/596,278

(22) Filed: Mar. 5, 2024

(30) Foreign Application Priority Data
Mar. 27, 2023 (JP) 2023-049414
Aug. 3, 2023 (JP) 2023-127009

(51) Int. Cl. C09G 1/02; H01L 21/3105

(52) U.S. Cl. CPC C09G 1/02; H01L 21/31053

(57) ABSTRACT

The present invention provides a means capable of polishing a Low-k material and silicon nitride at a high polishing removal rate and making a selection ratio of a polishing removal rate of the Low-k material to a polishing removal rate of the silicon nitride appropriate. The present invention provides a means capable of making a selection ratio of a polishing removal rate of silicon nitride to a polishing removal rate of silicon oxide appropriate while polishing silicon oxide and silicon nitride at a high polishing removal rate and capable of reducing defects on a silicon oxide surface after polishing.

The present invention is a polishing composition containing abrasive grains and an alkylamine compound having at least one linear or branched alkyl group having 2 or more and 15 or less carbon atoms, in which a pH is less than 7, and a zeta potential of the abrasive grains in the polishing composition is negative.

### CROSS-REFERENCE TO RELATED APPLICATION

The present application is based on Japanese Patent Application No. 2023-049414 filed on Mar. 27, 2023 and Japanese Patent Application No. 2023-127009 filed on Aug. 3, 2023, the entire disclosures of which are incorporated herein by reference.

### BACKGROUND

### 1. Technical Field

The present invention relates to a polishing composition, a polishing method, and a method for producing a semiconductor substrate.

### 2. Description of Related Arts

In recent years, new microfabrication techniques have been developed along with high integration and high performance of LSI (Large Scale Integration). A chemical mechanical polishing (CMP) method is one of such techniques and is frequently employed in an LSI fabrication process, particularly, planarization of an interlayer insulating film in a multilayer interconnection forming process, formation of a metal plug, and formation of embedded wiring (damascene wiring).

As a material for the interlayer insulating film in the multilayer interconnection forming process, a low dielectric constant (Low-k) material is being adopted in order to suppress the inter-wiring capacitance. Sioc (carbon-containing silicon oxide in which SiO: is doped with C) formed by a plasma CVD method is widely adopted as a low dielectric constant (Low-k) material.

As a technique for polishing SiOC, JP 2017-139349 A discloses a polishing composition containing: abrasive grains containing cerium; and hydroxyalkyl cellulose and having a pH of 6.0 or more. According to JP 2017-139349 A, with such a configuration, the polishing removal rate of SiOC can be improved.

### SUMMARY

Recently, a substrate containing both a Low-k material represented by SiOC and silicon nitride (Si₃N₄) has been used. In such a substrate, there is an increasing demand to polish a Low-k material and silicon nitride at an appropriate selection ratio of polishing removal rates (for example, the polishing removal rate of the Low-k material/the polishing removal rate of silicon nitride=1.0 or more and 2.0 or less) while polishing the Low-k material and the silicon nitride at a high polishing removal rate. However, according to the polishing composition described in JP 2017-139349 A, there is a problem in that such a demand is not satisfied.

A substrate containing both silicon oxide and silicon nitride has also been used. In such a substrate, there is an increasing demand to polish silicon oxide and silicon nitride at an appropriate selection ratio of polishing removal rates (for example, the polishing removal rate of silicon nitride/the polishing removal rate of silicon oxide=1.5 or more and 2.5 or less) while polishing the silicon oxide and the silicon nitride at a high polishing removal rate, and to further reduce defects on the silicon oxide surface after polishing.

The present invention has been made in view of the above circumstances, and an object thereof is to provide a means capable of polishing a Low-k material and silicon nitride at a high polishing removal rate and making a selection ratio of a polishing removal rate of the Low-k material to a polishing removal rate of the silicon nitride appropriate.

Another object of the present invention is to provide a means capable of making a selection ratio of a polishing removal rate of silicon nitride to a polishing removal rate of silicon oxide appropriate while polishing silicon oxide and silicon nitride at a high polishing removal rate and capable of reducing defects on a silicon oxide surface after polishing.

The present inventors have conducted intensive studies to solve the above problems. As a result, the present inventors have found that at least one of the above problems may be solved by a polishing composition containing abrasive grains and an alkylamine compound having at least one linear or branched alkyl group having 2 or more and 15 or less carbon atoms, in which a pH is less than 7, and a zeta potential of the abrasive grains in the polishing composition is negative, thereby completing the present invention.

### DETAILED DESCRIPTION

According to an embodiment of the present invention, there is provided a polishing composition containing abrasive grains and an alkylamine compound having at least one linear or branched alkyl group having 2 or more and 15 or less carbon atoms, in which a pH is less than 7, and a zeta potential of the abrasive grains in the polishing composition is negative. According to such a polishing composition of the present invention, a Low-k material and silicon nitride can be polished at a high polishing removal rate, and a selection ratio of a polishing removal rate of the Low-k material to a polishing removal rate of the silicon nitride can be made appropriate (for example, the polishing removal rate of the Low-k material/the polishing removal rate of silicon nitride=1.0 or more and 2.0 or less). According to the polishing composition of the present invention, it is possible to make a selection ratio of a polishing removal rate of silicon nitride to a polishing removal rate of silicon oxide appropriate (for example, the of silicon nitride/the polishing polishing removal rate removal rate of silicon oxide=1.5 or more and 2.5 or less) while polishing silicon oxide and silicon nitride at a high polishing removal rate and to reduce defects (for example, scratches) on a silicon oxide surface after polishing.

The reason why the above effect is obtained by the polishing composition of the present invention is not clear in detail. However, it is considered that the effect on the object to be polished containing a Low-k material and silicon nitride is exhibited by the following mechanism. The mechanism is based on speculation, and the technical scope of the present invention is not limited by the mechanism.

The surface of the Low-k material is generally hydrophobic, and the alkylamine compound is likely to adsorb to the Low-k material. When the alkylamine compound is adsorbed on the surface of the Low-k material, the chemical bond of the Low-k material is likely to be distorted and brittle. This increases the polishing removal rate of the Low-k material. The pH of the polishing composition according to the present invention is less than 7.0, and the zeta potential of the silicon nitride surface is positive under such conditions. The abrasive grains having a negative zeta potential contained in the polishing composition easily approach the silicon nitride surface having a positive zeta potential due to electrostatic attraction, and the polishing removal rate of silicon nitride is also increased. As a result, the polishing removal rates of the Low-k material and silicon nitride both are increased (for example, 300 Å/min or more), and the selection ratio of the polishing removal rate of the Low-k material to the polishing removal rate of the silicon nitride can be set to an appropriate selection ratio (for example, the polishing removal rate of the Low-k material/the polishing removal rate of silicon nitride=1.0 or more and 2.0 or less). According to the polishing composition of the present invention, defects (for example, scratches) on the surface of the object to be polished (particularly, silicon nitride) after polishing can be reduced.

Hereinafter, embodiments of the present invention will be described in detail; however, the present invention is not limited only to the following embodiments, and various modifications can be made within the scope of claims. The embodiments described in the present specification may be other embodiments by being arbitrarily combined. In the present specification, unless otherwise specified, operations and measurements of physical properties and the like are performed under conditions of room temperature (20° C. or higher and 25° C. or lower)/relative humidity of 40% RH or more and 50% RH or less.

### [Abrasive Grains]

The polishing composition according to the present invention contains abrasive grains. The abrasive grains have an action of mechanically polishing an object to be polished, and improve the polishing removal rate of the object to be polished by the polishing composition.

In the polishing composition of the present invention, the abrasive grains have a negative zeta potential. Here, the “zeta (ξ) potential” is a potential difference generated at an interface between a solid and a liquid in contact with each other when the solid and the liquid perform relative movement. When the zeta potential of the abrasive grains is 0 mV or more (0 mV or positive), the polishing removal rates of the Low-k material, silicon nitride, and silicon oxide decrease.

In the polishing composition of the present invention, the zeta potential of the abrasive grains is preferably −60 mV or more and −10 mV or less, more preferably −50 mV or more and −10 mV or less, and further preferably −45 mV or more and −15 mV or less. Since the abrasive grains have a zeta potential in such a range, the polishing removal rate of the object to be polished can be further improved. The selection ratio of the polishing removal rate of the Low-k material to the polishing removal rate of the silicon nitride can be made appropriate (for example, the polishing removal rate of the Low-k material/the polishing removal rate of silicon nitride=1.0 or more and 2.0 or less). The selection ratio of the polishing removal rate of silicon nitride to the polishing removal rate of silicon oxide can be made appropriate (for example, the polishing removal rate of silicon nitride/the polishing removal rate of silicon oxide=1.5 or more and 2.5 or less).

Here, the zeta potential of the abrasive grains in the polishing composition is a value measured by the method described in Examples. The zeta potential of the abrasive grains can be adjusted by the amount of an anionic group described below (particularly, an organic acid group) that the abrasive grains have, the pH of the polishing composition, and the like.

The type of abrasive grains is not particularly limited, and examples thereof include metal oxides such as silica, alumina, zirconia, and titania. The abrasive grains can be used singly or in combination of two or more kinds thereof. As the abrasive grains, a commercially available product or a synthetic product may be used.

The type of abrasive grains is preferably silica and more preferably colloidal silica. Examples of the method for producing colloidal silica include a sodium silicate method and a sol-gel method, and any colloidal silica produced by any production method is suitably used as the abrasive grains of the present invention. However, from the viewpoint of reducing metal impurities, colloidal silica produced by a sol-gel method capable of producing colloidal silica with high purity is preferable.

The production of colloidal silica by the sol-gel method can be performed using a conventionally known method, and specifically, colloidal silica can be obtained by performing a hydrolysis/condensation reaction using a hydrolyzable silicon compound (for example, alkoxysilane or a derivative thereof) as a raw material.

In some embodiments of the present invention, the colloidal silica contained in the polishing composition is preferably anionically modified colloidal silica and more preferably colloidal silica having an organic acid immobilized on the surface. The colloidal silica having an organic acid immobilized on the surface tends to have a larger absolute value of zeta potential in the polishing composition than normal colloidal silica having no organic acid immobilized thereon. Therefore, the zeta potential of the colloidal silica in the polishing composition is easy to adjust to negative.

Preferable examples of the colloidal silica having an organic acid immobilized on the surface include colloidal silica in which an organic acid group such as a carboxylic acid group, a sulfonic acid group, a phosphonic acid group, or an aluminate group is immobilized on the surface. Among them, from the viewpoint of easy production, colloidal silica having sulfonic acid and carboxylic acid immobilized on the surface is preferable, and colloidal silica having sulfonic acid immobilized on the surface is more preferable.

The immobilization of the organic acid on the surface of the colloidal silica is not achieved by simply allowing the colloidal silica and the organic acid to coexist. For example, when sulfonic acid, which is a kind of organic acid, is immobilized on colloidal silica, it is possible to perform the immobilization, for example, by the method described in “Sulfonic acid-functionalized silica through quantitative oxidation of thiol groups”, Chem. Commun. 246-247 (2003). Specifically, it is possible to obtain colloidal silica (sulfonic acid-modified colloidal silica) having sulfonic acid immobilized on the surface by coupling a silane coupling agent having a thiol group such as 3-mercaptopropyl trimethoxysilane to colloidal silica and then oxidizing the thiol group with hydrogen peroxide.

Alternatively, when carboxylic acid, which is a kind of organic acid, is immobilized on colloidal silica, it is possible to perform the immobilization, for example, by the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, it is possible to obtain colloidal silica (carboxylic acid-modified colloidal silica) having carboxylic acid immobilized on the surface by coupling a silane coupling agent containing a photoreactive 2-nitrobenzyl ester to colloidal silica and then irradiating with light.

The shape of the abrasive grains is not particularly limited, and may have a spherical shape or a non-spherical shape. Specific examples of the non-spherical shape include various shapes including a polygonal pole shape such as a triangle pole and a square pole, a cylindrical shape, a bale shape in which a central portion of a cylinder is bulged more than an end portion, a donut shape in which a central portion of a disk is penetrated, a plate shape, a so-called cocoon shape having a narrow part in a central portion, a so-called associated type spherical shape in which a plurality of particles are integrated, a so-called confetti shape having a plurality of protrusions on the surface thereof, a rugby ball shape, and the like, and the non-spherical shape is not particularly limited.

The size of the abrasive grains is not particularly limited. For example, the average primary particle size of the abrasive grains is preferably 5 nm or more, more preferably 8 nm or more, further preferably 10 nm or more, and particularly preferably 12 nm or more. As the average primary particle size of the abrasive grains increases, the polishing removal rate of the object to be polished by the polishing composition is improved. The average primary particle size of the abrasive grains is preferably 100 nm or less, more preferably 80 nm or less, further preferably 50 nm or less. As the average primary particle size of the abrasive grains decreases, it is easier to obtain a surface with fewer defects by polishing using the polishing composition. That is, the average primary particle size of the abrasive grains is preferably 5 nm or more and 100 nm or less, more preferably 8 nm or more and 80 nm or less, further preferably 10 nm or more and 50 nm or less, and particularly preferably 12 nm or more and 50 nm or less. The average primary particle size of the abrasive grains can be calculated, for example, based on the specific surface area (SA) of the abrasive grains calculated from the BET method on the assumption that the shape of the abrasive grains is a true spherical shape. In the present specification, as the average primary particle size of the abrasive grains, a value measured by the method described in Examples is adopted.

The average secondary particle size of the abrasive grains is preferably 10 nm or more, more preferably 15 nm or more, further preferably 20 nm or more, and particularly preferably 25 nm or more. As the average secondary particle size of the abrasive grains increases, the resistance during polishing is decreased, and polishing can be stably performed. The average secondary particle size of the abrasive grains is preferably 400 nm or less, more preferably 300 nm or less, further preferably 200 nm or less, particularly preferably 100 nm or less, and most preferably 80 nm or less. As the average secondary particle size of the abrasive grains decreases, the surface area per unit mass of the abrasive grains increases, the frequency of contact with the object to be polished is improved, and the polishing removal rate is further improved. That is, the average secondary particle size of the abrasive grains is preferably 10 nm or more and 400 nm or less, more preferably 15 nm or more and 300 nm or less, further preferably 20 nm or more and 200 nm or less, still more preferably 25 nm or more and 100 nm or less, and particularly preferably 25 nm or more and 80 nm or less. The average secondary particle size of the abrasive grains can be measured by, for example, a dynamic light scattering method represented by a laser diffraction scattering method.

The average association degree of the abrasive grains is preferably 5.0 or less, more preferably 4.0 or less, further preferably 3.0 or less, and particularly preferably 2.5 or less. As the average association degree of the abrasive grains decreases, defects can be further reduced. The average association degree of the abrasive grains is also preferably 1.0 or more, more preferably 1.5 or more, and further preferably 2.0 or more. The average association degree thereof is obtained by dividing the value of the average secondary particle size of the abrasive grains by the value of the average primary particle size of the abrasive grains. As the average association degree of the abrasive grains increases, there is a favorable effect that the polishing removal rate of the object to be polished by the polishing composition is improved.

The upper limit of the aspect ratio of the abrasive grains in the polishing composition is not particularly limited, and is preferably less than 2.0, more preferably 1.8 or less, and further preferably 1.5 or less. Within such a range, defects on the surface of the object to be polished can be further reduced. The aspect ratio is an average of values obtained by taking the smallest rectangle circumscribing the image of an abrasive grain particle with a scanning electron microscope and dividing the length of a long side of the rectangle by the length of a short side of the same rectangle, and can be determined using general image analysis software. The lower limit of the aspect ratio of the abrasive grains in the polishing composition is not particularly limited, and is preferably 1.0 or more and more preferably 1.2 or more.

In the particle size distribution of the abrasive grains determined by a laser diffraction scattering method, the lower limit of a ratio D90/D10 of a particle diameter when the integrated particle mass reaches 90% of the total particle mass from the fine particle side (D90) and a particle diameter when the integrated particle mass reaches 10% of the total particle mass from the fine particle side (D10) is not particularly limited, and is preferably 1.1 or more, more preferably 1.4 or more, further preferably 1.7 or more, and most preferably 2.0 or more. In the particle size distribution of the abrasive grains in the polishing composition determined by a laser diffraction scattering method, the upper limit of the ratio D90/D10 of the particle diameter when the integrated particle mass reaches 90% of the total particle mass from the fine particle side (D90) and the particle diameter when the integrated particle mass reaches 10% of the total particle mass from the fine particle side (D10) is not particularly limited, and is preferably 3.0 or less and more preferably 2.5 or less. Within such a range, defects on the surface of the object to be polished can be further reduced.

The size of the abrasive grains (average primary particle size, average secondary particle size, aspect ratio, D90/D10, or the like) can be appropriately controlled by selection of the method for producing the abrasive grains, and the like.

The concentration (content) of the abrasive grains is not particularly limited, and is preferably 0.5% by mass or more, more preferably 0.8% by mass or more, further preferably 18 by mass or more, still more preferably more than 1% by mass, and particularly preferably 1.5% by mass or more, with respect to the total mass of the polishing composition. The upper limit of the concentration (content) of the abrasive grains is preferably 20% by mass or less, more preferably 15% by mass or less, further preferably 10% by mass or less, and particularly preferably 5% by mass or less, with respect to the total mass of the polishing composition. That is, the concentration (content) of the abrasive grains is preferably 0.5% by mass or more and 20% by mass or less, more preferably 0.8% by mass or more and 20% by mass or less, further preferably 1% by mass or more and 15% by mass or less, still more preferably more than 1% by mass and 10% by mass or less, and particularly preferably 1.5% by mass or more and 5% by mass or less, with respect to the total mass of the polishing composition. Within such a range, the polishing removal rate can be improved while suppressing the cost. When the polishing composition contains two or more kinds abrasive grains, the concentration (content) of the abrasive grains means the total amount thereof.

### [Alkylamine Compound]

The polishing composition according to the present invention contains an alkylamine compound having at least one linear or branched alkyl group having 2 or more and 15 or less carbon atoms (hereinafter, also simply referred to as “alkylamine compound”). As described above, the alkylamine compound has an effect of distorting the chemical bond of the Low-k material, and can improve the polishing removal rate of the Low-k material. The alkylamine compound can reduce defects (for example, scratches) on the silicon oxide surface after polishing.

The alkylamine compound according to the present invention has at least one linear or branched alkyl group having 2 or more and 15 or less carbon atoms. As long as the compound has such an alkyl group, any of a monoalkylamine compound (primary alkylamine compound), a dialkylamine compound (secondary alkylamine compound), and a trialkylamine compound (tertiary alkylamine compound) can be used.

As one of factors of increasing scratches, it is considered that the abrasive grains and organic residues (for example, polishing pad scraps) form a composite, and the composite causes local polishing. The alkylamine compound according to the present invention having at least one linear or branched alkyl group having 2 or more and 15 or less carbon atoms is easily adsorbed to both the abrasive grains and the organic residues (for example, polishing pad scraps). As a result, it is considered that steric hindrance occurs between the abrasive grains and the organic residues, the formation of a complex of the abrasive grains and the organic residues is suppressed, and scratches are suppressed.

In the case of an alkylamine compound having only an alkyl group having one carbon atom (methyl group), the effect of distorting the chemical bond of the Low-k material is reduced, and the polishing removal rate of the Low-k material is reduced. The alkylamine compound is difficult to adsorb to both the abrasive grains and the organic residues (for example, polishing pad scraps), it is difficult to suppress the formation of a complex due to steric hindrance, and scratches tend to increase.

In the case of an alkylamine compound having only an alkyl group having more than 15 carbon atoms, the compound is easily adsorbed on the surface of silicon nitride and acts like a protective film of silicon nitride, and the polishing removal rate of silicon nitride is reduced. The abrasive grains are easily aggregated, and scratches increase. In the case of a dialkylamine compound (secondary alkylamine compound) and a trialkylamine compound (tertiary alkylamine compound), as long as the compound has at least one alkyl group having 2 or more and 15 or less carbon atoms, the other alkyl group may be an alkyl group having one carbon atom (methyl group) or an alkyl group having more than 15 carbon atoms, but a compound having only an alkyl group having 2 or more and 15 or less carbon atoms is preferable.

Examples of the linear or branched alkyl group having 2 or more and 15 or less carbon atoms include an ethyl group, a n-propyl group, an isopropyl group, a 2-methylpropyl group, a n-butyl group, an isobutyl group, a sec-butyl group, a tert-butyl group, a n-pentyl group, an iso-amyl group, a tert-pentyl group, a neopentyl group, a n-hexyl group, a 3-methylpentane-2-yl group, a 3-methylpentane-3-yl group, a 4-methylpentyl group, a 4-methylpentane-2-yl group, a 1,3-dimethylbutyl group, a 3,3-dimethylbutyl group, a 3,3-dimethylbutane-2-yl group, a n-heptyl group, a 1-methylhexyl group, a 3-methylhexyl group, a 4-methylhexyl group, a 5-methylhexyl a 1-ethylpentyl group, group, a 1-(n-propyl) butyl group, a 1,1-dimethylpentyl group, a 1,4-dimethylpentyl group, a 1,1-diethylpropyl group, a 1,3,3-trimethylbutyl group, a 1-ethyl-2,2-dimethylpropyl group, a n-octyl group, a 2-ethylhexyl group, a 2-methylhexane-2-yl group, a 2,4-dimethylpentane-3-yl group, a 1,1-dimethylpentane-1-yl group, a 2,2-dimethylhexane-3-yl group, a 2,3-dimethylhexane-2-yl group, a 2,5-dimethylhexane-2-yl group, a 2,5-dimethylhexane-3-yl group, a 3,4-dimethylhexane-3-yl group, a 3,5-dimethylhexane-3-yl group, a 1-methylheptyl group, a 2-methylheptyl group, a 5-methylheptyl group, a 2-methylheptane-2-yl group, a 3-methylheptane-3-yl group, a 4-methylheptane-3-yl group, a 4-methylheptane-4-yl group, a 1-ethylhexyl group, a 2-ethylhexyl group, a 1-propylpentyl group, a 2-propylpentyl group, a 1,1-dimethylhexyl group, a 1,4-dimethylhexyl group, a 1,5-dimethylhexyl group, a 1-ethyl-1-methylpentyl group, a 1-ethyl-4-methylpentyl group, a 1,1,4-trimethylpentyl group, a 2,4,4-trimethylpentyl group, 1-isopropyl-1,2-dimethylpropyl group, a 1,1,3,3-tetramethylbutyl group, a n-nonyl group, a 1-methyloctyl group, a 6-methyloctyl group, a 1-ethylheptyl group, a 1-(n-butyl) pentyl group, a 4-methyl-1-(n-propyl) pentyl group, a 1,5,5-trimethylhexyl group, a 1,1,5-trimethylhexyl group, a 2-methyloctane-3-yl group, a n-decyl group, a 1-methylnonyl group, a 1-ethyloctyl group, a 1-(n-butyl) hexyl group, a 1,1-dimethyloctyl group, a 3,7-dimethyloctyl group, a n-undecyl group, a 1-methyldecyl group, a 1-ethylnonyl group, a n-dodecyl group, a 1-methylundecyl group, a n-tridecyl group, a n-tetradecyl group, a 1-methyltridecyl group, a n-pentadecyl group, and the like. The two or more alkyl groups that the dialkylamine compound (secondary alkylamine and the compound) trialkylamine compound (tertiary alkylamine compound) have may be the same or different from each other.

More specific examples of the alkylamine compound include monoalkylamine compounds (primary alkylamine compounds) such as ethylamine, n-propylamine, isopropylamine, n-butylamine, isobutylamine, sec-butylamine, tert-butylamine, n-pentylamine, n-hexylamine, n-heptylamine, n-octylamine, n-nonylamine, n-decylamine, n-undecylamine, n-dodecylamine, n-tridecylamine, n-tetradecylamine, and n-pentadecylamine;

dialkylamine compounds (secondary alkylamine compounds) such as diethylamine, di-n-propylamine, diisopropylamine, di-n-butylamine, diisobutylamine, di-sec-butylamine, di-n-pentylamine, ethylmethylamine, methyl-n-propylamine, methyl-n-butylamine, methyl-n-pentylamine, methyl-n-octylamine, methyl-n-decylamine, methyl-n-dodecylamine, methyl-n-tetradecylamine, methyl-n-hexadecylamine, methyl-n-octadecylamine, ethylisopropylamine, ethyl-n-butylamine, ethyl-n-pentylamine, ethyl-n-octylamine, di-n-hexylamine, di-n-octylamine, and di-n-dodecylamine; and trialkylamine compounds (tertiary alkylamine compounds) such as triethylamine, tri-n-propylamine, tri-n-butylamine, tri-n-pentylamine, tri-n-hexylamine, tri-n-octylamine, tri-n-dodecylamine, dimethylethylamine, dimethyl-n-butylamine, dimethyl-n-hexylamine, dimethyl-n-octylamine, dimethyl-n-decylamine, diethyl-n-decylamine, dimethyl-n-dodecylamine, and dimethyl-n-tetradecylamine, and the like.

These alkylamine compounds may be used singly or in combination of two or more kinds thereof. As the alkylamine compound, a commercially available product or a synthetic product may be used.

From the viewpoint of further improving the effect of the present invention, the alkylamine compound is preferably a monoalkylamine compound having only one linear or branched alkyl group having 2 or more and 15 or less carbon atoms. From the viewpoint of further reducing scratches on the surface of the object to be polished after polishing, the number of carbon atoms of the alkyl group that the alkylamine compound according to the present invention has is more preferably 2 or more and 7 or less and further preferably 2 or more and 6 or less. When the number of carbon atoms of the alkyl group that the alkylamine compound has increases, the abrasive grains are easily aggregated, and the number of scratches tends to increase.

In addition, from the viewpoint of easy availability and cost reduction, the alkyl group is preferably linear.

From the above, the alkylamine compound according to the present invention is more preferably at least one monoalkylamine compound selected from the group consisting of ethylamine, n-propylamine, n-butylamine, n-pentylamine, n-hexylamine, n-heptylamine, n-octylamine, n-nonylamine, n-decylamine, n-undecylamine, and n-dodecylamine. The alkylamine compound according to the present invention is further preferably at least one monoalkylamine compound selected from the group consisting of ethylamine, n-propylamine, n-butylamine, n-pentylamine, n-hexylamine, and n-heptylamine, and is particularly preferably at least one monoalkylamine compound selected from the group consisting of ethylamine, n-propylamine, n-butylamine, n-pentylamine, and n-hexylamine.

The lower limit of the concentration (content) of the alkylamine compound with respect to the total mass of the polishing composition is preferably 0.001% by mass or more, more preferably 0.005% by mass or more, further preferably 0.007% by mass or more, and particularly preferably 0.01% by mass or more. The upper limit of the concentration (content) of the alkylamine compound with respect to the total mass of the polishing composition is preferably 38 by mass or less, more preferably 2% by mass or less, further preferably 1% by mass or less, and particularly preferably 0.58 by mass or less. That is, the concentration (content) of the alkylamine compound with respect to the total mass of the polishing composition is preferably 0.001% by mass or more and 3% by mass or less, more preferably 0.005% by mass or more and 2% by mass or less, further preferably 0.007% by mass or more and 1% by mass or less, and particularly preferably 0.01% by mass or more and 0.5% by mass or less. With the concentration in such a range, stability can be secured while achieving the effect of reducing defects on the silicon oxide surface.

When the polishing composition contains two or more kinds of alkylamine compounds, the concentration (content) of the alkylamine compound means the total amount thereof.

### [Electrical Conductivity Adjusting Agent]

The polishing composition according to an embodiment of the present invention preferably further contains an electrical conductivity adjusting agent. The electrical conductivity adjusting agent acts to further improve the polishing removal rate of silicon oxide or improve the dispersion stability of the polishing composition, for example, by adjusting the electrical conductivity of the polishing composition to an appropriate range.

The electrical conductivity adjusting agent is not particularly limited as long as it is a compound having an electrical conductivity adjusting function, and for example, a salt compound can be used. Examples of the salt compound include a salt of an acid compound, a salt of a basic compound, and the like. The salt of the acid compound may be an organic acid salt or an inorganic acid salt.

Specific examples of the electrical conductivity adjusting agent include sodium nitrate, potassium nitrate, ammonium nitrate, magnesium nitrate, calcium nitrate, sodium nitrite, potassium nitrite, lithium acetate, sodium acetate, potassium acetate, ammonium acetate, calcium acetate, calcium lactate, lithium benzoate, sodium benzoate, potassium benzoate, lithium carbonate, sodium carbonate, potassium carbonate, magnesium carbonate, calcium carbonate, lithium hydrogen carbonate, sodium hydrogen carbonate, potassium hydrogen carbonate, ammonium carbonate, sodium bicarbonate, sodium sulfate, potassium sulfate, ammonium sulfate, calcium sulfate, magnesium sulfate, sodium sulfite, potassium sulfite, calcium sulfite, magnesium sulfite, potassium thiosulfate, lithium sulfate, magnesium sulfate, sodium thiosulfate, sodium bisulfite, sodium hydrogensulfate, potassium bisulfate, disodium oxalate, dipotassium oxalate, ammonium oxalate, ammonium citrate, disodium glutarate, lithium fluoride, sodium fluoride, potassium fluoride, calcium fluoride, ammonium fluoride, potassium chloride, sodium chloride, ammonium chloride, calcium chloride, potassium bromide, sodium bromide, ammonium bromide, calcium bromide, sodium potassium iodide, potassium iodide, triiodide, calcium iodide, trilithium phosphate, tripotassium phosphate, trisodium phosphate, triammonium phosphate, sodium monohydrogen phosphate, potassium monohydrogen phosphate, sodium dihydrogen phosphate, potassium dihydrogen phosphate, ammonium dihydrogen phosphate, and the like. These electrical conductivity adjusting agents may be used singly or as a mixture of two or more kinds thereof.

Among these electrical conductivity adjusting agents, ammonium sulfate, potassium hydrogen carbonate, ammonium carbonate, potassium acetate, potassium nitrate, ammonium nitrate, dipotassium oxalate, and ammonium oxalate are preferable.

The concentration (content) of the electrical conductivity adjusting agent may be appropriately selected so as to have a preferable electrical conductivity value of the polishing composition described below. According to some embodiments, the concentration (content) of the electrical conductivity adjusting agent is preferably 0.01% by mass or more, more preferably 0.05% by mass or more, and further preferably 0.1% by mass or more, with respect to 100% by mass of the total mass of the polishing composition. The concentration (content) of the electrical conductivity adjusting agent is preferably 5.0% by mass or less, more preferably 3.0% by mass or less, and further preferably 2.0% by mass or less, with respect to 100% by mass of the total mass of the polishing composition. That is, the concentration (content) of the electrical conductivity adjusting agent is preferably 0.01% by mass or more and 5.0% by mass or less, more preferably 0.05% by mass or more and 3.0% by mass or less, and further preferably 0.1% by mass or more and 2.0% by mass or less, with respect to 100% by mass of the total mass of the polishing composition. With the concentration (content) in such a range, stability can be secured while improving the polishing removal rate of silicon oxide.

When the polishing composition contains two or more kinds of electrical conductivity adjusting agents, the concentration (content) of the electrical conductivity adjusting agent means the total amount thereof.

### [pH and pH Adjusting Agent]

The pH of the polishing composition according to the present invention is less than 7.0. When the pH is 7.0 or more, the polishing removal rates of the Low-k material and silicon nitride decrease. The pH is preferably 1.0 or more, more preferably 1.5 or more, and further preferably 2.0 or more. The pH is preferably 6.0 or less, more preferably 5.0 or less, and further preferably 4.5 or less. That is, the pH of the polishing composition according to the present invention is preferably 1.0 or more and 6.0 or less, more preferably 1.5 or more and 5.0 or less, and further preferably 2.0 or more and 4.5 or less.

The polishing composition according to the present invention preferably contains a pH adjusting agent for adjusting the pH. The pH adjusting agent may be either an acid or a base, or may be either an inorganic compound or an organic compound. The pH adjusting agent can be used singly or as a mixture of two or more kinds thereof.

Specific examples of the acid that can be used as the pH adjusting agent include inorganic acids such as hydrochloric acid, sulfuric acid, nitric acid, hydrofluoric acid, boric acid, carbonic acid, hypophosphorous acid, phosphorous acid, and phosphoric acid; and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic and acid, phenoxyacetic acid.

Examples of the base that can be used as the pH adjusting agent include amines such as aliphatic amines and aromatic amines, organic bases such as quaternary ammonium hydroxide, hydroxides of alkali metals such as sodium hydroxide and potassium hydroxide, hydroxides of Group 2 elements, ammonia, and the like.

The addition amount of the pH adjusting agent is not particularly limited, and may be appropriately adjusted so that the polishing composition has a desired pH. The pH of the polishing composition can be measured by, for example, a pH meter, and specifically, can be measured by the method described in Examples.

### [Dispersing Medium]

The polishing composition according to the present invention preferably further contains a dispersing medium. Examples of the dispersing medium include water; alcohols such as methanol, ethanol, and ethylene glycol; ketones such as acetone, mixtures thereof; and the like. Among them, water is preferable as the dispersing medium. That is, according to a more preferable embodiment of the present invention, the dispersing medium contains water. According to a further preferred embodiment of the present invention, the dispersing medium substantially consists of water. The term “substantially” as described above is intended to mean that a dispersing medium other than water can be contained as long as the objective effect of the present invention can be achieved, and more specifically, the dispersing medium is preferably composed of 90% by mass or more and 100% by mass or less of water and 0% by mass or more and 10% by mass or less of a dispersing medium other than water, and more preferably composed of 99% by mass or more and 100% by mass or less of water and 0% by mass or more and 18 by mass or less of a dispersing medium other than water. Most preferably, the dispersing medium is water.

From the viewpoint of preventing the action of the components contained in the polishing composition from being inhibited, water not containing impurities as much as possible is preferable as the dispersing medium, and specifically, pure water or ultrapure water from which impurity ions are removed with an ion exchange resin and then foreign substances are removed through a filter, or distilled water is more preferable.

### [Electrical Conductivity of Polishing Composition]

The electrical conductivity (EC) of the polishing composition according to the present invention is not particularly limited, and is preferably 0.5 mS/cm or more, more preferably 1 mS/cm or more, and further preferably 1.5 mS/cm or more. The electrical conductivity (EC) of the polishing composition according to the present invention is preferably 20 mS/cm or less, more preferably 15 mS/cm or less, and further preferably 10 mS/cm or less. That is, the electrical conductivity (EC) of the polishing composition according to the present invention is preferably 0.5 mS/cm or more and 20 mS/cm or less, more preferably 1 mS/cm or more and 15 mS/cm or less, and further preferably 1.5 mS/cm or more and 10 mS/cm or less. When the electrical conductivity (EC) of the polishing composition is within such a range, the polishing removal rates of the Low-k material and silicon nitride can be maintained high, and repelling between the abrasive grains can be appropriately adjusted to ensure stability. The polishing removal rate of silicon oxide can be further improved. The electrical conductivity of the polishing composition can be adjusted by the type and amount of the above-described electrical conductivity adjusting agent, the type and amount of the pH adjusting agent, and the like. The electrical conductivity of the polishing composition can be measured by the method described in Examples.

### [Other Components]

The polishing composition of the present invention may further contain known additives that can be used in the polishing composition, such as a water-soluble polymer, a complexing agent, a metal anticorrosive, an antiseptic agent, an antifungal agent, an oxidizing agent, a reducing agent, and a surfactant, as necessary. Among them, the polishing composition preferably contains an antifungal agent. The polishing composition according to the present invention is acidic. Therefore, the polishing composition more preferably contains an antifungal agent. That is, in an embodiment of the present invention, the polishing composition is substantially composed of abrasive grains, an alkylamine compound having at least one linear or branched alkyl group having 2 or more and 15 or less carbon atoms, a dispersing medium, and at least one selected from the group consisting of an electrical conductivity adjusting agent, a pH adjusting agent, and an antifungal agent. Here, the phrase “the polishing composition is substantially composed of abrasive grains, an alkylamine compound having at least one linear or branched alkyl group having 2 or more and 15 or less carbon atoms, a dispersing medium, and at least one selected from the group consisting of an electrical conductivity adjusting agent, a pH adjusting agent, and an antifungal agent” means that the total content of the abrasive grains, the alkylamine compound having at least one linear or branched alkyl group having 2 or more and 15 or less carbon atoms, the dispersing medium, and at least one selected from the group consisting of an electrical conductivity adjusting agent, a pH adjusting agent, and an antifungal agent exceeds 99% by mass with respect to the total mass of the polishing composition (upper limit: 100% by mass). According to a preferred embodiment, the polishing composition is composed of abrasive grains, an alkylamine compound having at least one linear or branched alkyl group having 2 or more and 15 or less carbon atoms, a dispersing medium, a pH adjusting agent, and an antifungal agent (the total content=100% by mass). According to another preferred embodiment, the polishing composition is composed of abrasive grains, an alkylamine compound having at least one linear or branched alkyl group having 2 or more and 15 or less carbon atoms, a dispersing medium, an electrical conductivity adjusting agent, a pH adjusting agent, and an antifungal agent (the total content=100% by mass). According to still another preferred embodiment, the polishing composition is composed of abrasive grains, an alkylamine compound having at least one linear or branched alkyl group having 2 or more and 15 or less carbon atoms, a dispersing medium, and a pH adjusting agent (the total content=100% by mass). According to still another preferred embodiment, the polishing composition is composed of abrasive grains, an alkylamine compound having at least one linear or branched alkyl group having 2 or more and 15 or less carbon atoms, a dispersing medium, an electrical conductivity adjusting agent, and a pH adjusting agent (the total content=100% by mass).

Hereinafter, an antifungal agent (antiseptic agent), which is another preferable component, will be described. An oxidizing agent will also be described.

### (Antifungal Agent)

Examples of the antifungal agent (antiseptic agent) that can be added to the polishing composition according to the present invention include isothiazoline-based antiseptic agents such as 2-methyl-4-isothiazoline-3-one and 5-chloro-2-methyl-4-isothiazoline-3-one, paraoxybenzoic acid esters, phenoxyethanol, and the like. These antifungal agents (antiseptic agents) may be used singly or in combination of two or more kinds thereof.

### (Oxidizing Agent)

The polishing composition according to the present invention preferably does not substantially contain an oxidizing agent. When the oxidizing agent is contained in the polishing composition, the surface of the object to be polished is oxidized to generate an oxide film, and there is a concern that the polishing time becomes long. Specific examples of the oxidizing agent described herein include hydrogen peroxide (H₂O₂), sodium persulfate, ammonium persulfate, sodium dichloroisocyanurate, and the like. The fact that the polishing composition does not substantially contain an oxidizing agent means that the polishing composition does not at least intentionally contain an oxidizing agent. Therefore, a polishing composition inevitably containing a trace amount of an oxidizing agent derived from a raw material, a production method, or the like is included in the concept of the polishing composition that does not substantially contain an oxidizing agent. For example, the concentration (content) of the oxidizing agent with respect to the total mass of the polishing composition is preferably 0.01% by mass (100 ppm by mass) or less, more preferably less than 0.01% by mass (100 ppm by mass), and further preferably 0.005% by mass (50 ppm by mass) or less. The lower limit of the concentration (content) of the oxidizing agent is preferably 0% by mass or more and more preferably 0.0005% by mass (5 ppm by mass) or more.

### [Form of Polishing Composition]

The polishing composition according to the present invention is typically supplied to an object to be polished in the form of a polishing liquid containing the polishing composition, and is used for polishing the object to be polished. The polishing composition according to the present invention may be, for example, diluted (typically, diluted with water) and used as polishing liquid, or may be used as it is as a polishing liquid. That is, the concept of the polishing composition according to the present invention includes both a polishing composition (working slurry) supplied to an object to be polished and used for polishing the object to be polished and a concentrated solution (a stock solution of a working slurry) diluted and used for polishing. The concentration rate of the concentrated solution can be, for example, about 2 times or more and 100 times or less on a volume basis, and usually about 3 times or more and 50 times or less is appropriate.

### [Object to be Polished]

The object to be polished according to the present invention is not particularly limited, and examples thereof include single crystal silicon, polycrystalline silicon (polysilicon), polycrystalline silicon doped with an n-type or p-type impurity, amorphous silicon, amorphous silicon doped with an n-type or p-type impurity, silicon oxide, silicon nitride, silicon carbonitride (SiCN), a metal, SiGe, a carbon-containing material, a low dielectric constant material (Low-k material), and the like.

Examples of the object to be polished containing silicon oxide include a TEOS type silicon oxide film (hereinafter, also simply referred to as “TEOS” or “TEOS film”) produced using tetraethyl orthosilicate as a precursor, an HDP (High Density Plasma) film, a USG (Undoped Silicate Glass) film, a PSG (Phosphorus Silicate Glass) film, a BPSG (Boron-Phospho Silicate Glass) film, an RTO (Rapid Thermal Oxidation) film, and the like.

Examples of the metal include tungsten, copper, aluminum, cobalt, hafnium, nickel, gold, silver, platinum, palladium, rhodium, ruthenium, iridium, osmium, and the like.

Examples of the carbon-containing material include materials other than the Low-k material such as amorphous carbon, spin-on carbon (SOC), diamond-like carbon (DLC), nanocrystalline diamond, and graphene.

The low dielectric constant material (Low-k material) is a material having a relative dielectric constant k lower than that of silicon oxide, preferably a material having a relative dielectric constant k of 3.0 or less. Specific examples thereof include silicon carbide (Sic), carbon-containing silicon oxide (SiOC), silicon oxide containing a methyl group, benzocyclobutene (BCB), fluorinated silicon oxide (SiOF), HSQ (hydrogen silsesquioxane), MSQ (methyl silsesquioxane), HMSQ (hydride-methyl silsesquioxane), a polyimide-based polymer, an arylene ether-based polymer, a cyclobutene-based polymer, perfluorocyclobutene (PFCB), and the like.

The object to be polished may be a commercially available product or may be manufactured by a known method.

According to some embodiments, the object to be polished preferably contains a Low-k material and silicon nitride. Therefore, according to a preferred embodiment of the present invention, the polishing composition is used for polishing an object to be polished containing a Low-k material and silicon nitride. The Low-k material is preferably carbon-containing silicon oxide (SiOC).

According to some embodiments, the object to be polished preferably contains silicon oxide and silicon nitride. Therefore, according to a preferred embodiment of the present invention, the polishing composition is used for polishing an object to be polished containing silicon oxide and silicon nitride.

### [Method for Producing Polishing Composition]

A method for producing a polishing composition according to the present embodiment is not particularly limited, and for example, the polishing composition can be obtained by stirring and mixing abrasive grains, an alkylamine compound having at least one linear or branched alkyl group having 2 or more and 15 or less carbon atoms, a dispersing medium, and other additives added as necessary. Details of each component are as described above.

The temperature at which respective components are mixed is not particularly limited, and is preferably 10° C. or higher and 40° C. or lower, and heating may be performed in order to increase the rate of dissolution. The mixing time is also not particularly limited as long as the mixture can be uniformly mixed.

### [Polishing Method and Method for Producing Semiconductor Substrate]

As described above, the polishing composition according to some embodiments of the present invention is particularly suitably used for polishing an object to be polished having a Low-k material and silicon nitride. Therefore, the present invention provides a polishing method for polishing an object to be polished containing a Low-k material and silicon nitride by the polishing composition according to the present invention. The present invention provides a method for producing a semiconductor substrate, including polishing a semiconductor substrate containing a Low-k material and silicon nitride by the polishing method described above.

The polishing composition according to some embodiments of the present invention is particularly suitably used for polishing an object to be polished having silicon oxide and silicon nitride. Therefore, the present invention provides a polishing method for polishing an object to be polished containing silicon oxide and silicon nitride by the polishing composition according to the present invention. The present invention provides a method for producing a semiconductor substrate, including polishing a semiconductor substrate containing silicon oxide and silicon nitride by the polishing method described above.

As a polishing apparatus, it is possible to use a general polishing apparatus in which a holder for holding a substrate or the like having an object to be polished and a motor or the like capable of changing the number of revolutions are attached and which has a polishing table to which a polishing pad (polishing cloth) can be attached.

As the polishing pad, a general nonwoven fabric, polyurethane, a porous fluororesin, and the like can be used without particular limitation. The polishing pad is preferably grooved such that a polishing liquid is accumulated.

Regarding the polishing conditions, for example, the rotation speeds of the polishing table (platen) and the carrier (head) are preferably 10 rpm (0.17 s⁻¹) or more and 500 rpm (8.33 s⁻¹) or less. The pressure (polishing pressure) applied to the substrate having the object to be polished is preferably 0.5 psi (3.45 kPa) or more and 10 psi (68.9 kPa) or less.

The method of supplying the polishing composition to the polishing pad is not particularly limited, and for example, a method of continuously supplying the polishing composition by a pump or the like is adopted. This supply amount is not limited, but it is preferable that the surface of the polishing pad is covered with the polishing composition according to the present invention at all times.

The polishing composition according to the present embodiment may be a one-pack type or a multi-pack type including a two-pack type. The polishing composition according to the present invention may be prepared by diluting a stock solution of the polishing composition, for example, three times or more using a diluent such as water.

### [Polishing Removal Rate]

As described above, the polishing composition according to the present invention can polish the Low-k material, silicon nitride, and silicon oxide at a high polishing removal rate.

In the present invention, the polishing removal rate of the Low-k material is preferably 300 Å/min or more, and may be 350 Å/min or more, 400 Å/min or more, 500 Å/min or more, 550 Å/min or more, or 600 Å/min or more. The polishing removal rate of silicon nitride is preferably 300 Å/min or more, and may be 350 Å/min or more, 370 Å/min or more, 400 Å/min or more, 450 Å/min or more, 500 Å/min or more, 550 Å/min or more, 600 Å/min or more, 650 Å/min or more, or 670 Å/min or more. The polishing removal rate of silicon oxide is preferably 250 Å/min or more, and may be 300 Å/min or more, 310 Å/min or more, 320 Å/min or more, 330 Å/min or more, 340 Å/min or more, 350 Å/min or more, or 360 Å/min or more.

### [Selection Ratio]

As described the polishing composition above, according to the present invention can control the ratio of the polishing removal rate of the Low-k material to the polishing removal rate of the silicon nitride (hereinafter, also referred to as selection ratio A) in an appropriate range. As described above, the polishing composition according to the present invention can control the ratio of the polishing removal rate of silicon nitride to the polishing removal rate of silicon oxide (hereinafter, also referred to as selection ratio B) in an appropriate range.

In the present invention, the ratio of the polishing removal rate of the Low-k material to the polishing removal rate of the silicon nitride (selection ratio A, the polishing removal rate of the Low-k material/the polishing removal rate of the silicon nitride) is preferably 1.0 or more, more preferably 1.1 or more, further preferably 1.2 or more, and particularly preferably 1.4 or more. The ratio of the polishing removal rate of the Low-k material to the polishing removal rate of the silicon nitride (selection ratio A, the polishing removal rate of the Low-k material/the polishing removal rate of the silicon nitride) is preferably 2.0 or less, more preferably 1.9 or less, further preferably 1.8 or less, and particularly preferably 1.7 or less. That is, the selection ratio A may be 1.0 or more and 2.0 or less, 1.0 or more and 1.9 or less, 1.0 or more and 1.8 or less, or 1.0 or more and 1.7 or less. The selection ratio A may be 1.1 or more and 2.0 or less, 1.1 or more and 1.9 or less, 1.1 or more and 1.8 or less, or 1.1 or more and 1.7 or less. The selection ratio A may be 1.2 or more and 2.0 or less, 1.2 or more and 1.9 or less, 1.2 or more and 1.8 or less, or 1.2 or more and 1.7 or less. The selection ratio A may be 1.4 or more and 2.0 or less, 1.4 or more and 1.9 or less, 1.4 or more and 1.8 or less, or 1.4 or more and 1.7 or less. When the selection ratio A is out of the above range, the surface state of the finally obtained object to be polished after polishing may be deteriorated.

In the present invention, the ratio of the polishing removal rate of silicon nitride to the polishing removal rate of silicon oxide (selection ratio B, the polishing removal rate of silicon nitride/the polishing removal rate of silicon oxide) is preferably 1.3 or more, more preferably 1.4 or more, further preferably 1.5 or more, and particularly preferably 1.6 or more. The ratio of the polishing removal rate of silicon nitride to the polishing removal rate of silicon oxide (selection ratio B, the polishing removal rate of silicon nitride/the polishing removal rate of silicon oxide) is preferably 3.0 or less, more preferably 2.9 or less, further preferably 2.8 or less, still more preferably 2.5 or less, and particularly preferably 2.4 or less. That is, the selection ratio B may be 1.3 or more and 3.0 or less, 1.3 or more and 2.9 or less, 1.3 or more and 2.8 or less, 1.3 or more and 2.5 or less, or 1.3 or more and 2.4 or less. The selection ratio B may be 1.4 or more and 3.0 or less, 1.4 or more and 2.9 or less, 1.4 or more and 2.8 or less, 1.4 or more and 2.5 or less, or 1.4 or more and 2.4 or less. The selection ratio B may be 1.5 or more and 3.0 or less, 1.5 or more and 2.9 or less, 1.5 or more and 2.8 or less, 1.5 or more and 2.5 or less, or 1.5 or more and 2.4 or less. The selection ratio B may be 1.6 or more and 3.0 or less, 1.6 or more and 2.9 or less, 1.6 or more and 2.8 or less, 1.6 or more and 2.5 or less, or 1.6 or more and 2.4 or less. When the selection ratio B is out of the above range, the surface state of the finally obtained object to be polished after polishing may be deteriorated.

### [Scratches]

As described above, the polishing composition according to the present invention can reduce defects (for example, scratches) on the surface of the object to be polished (particularly, silicon nitride and/or silicon oxide) after polishing can be reduced.

In some embodiments of the present invention, the number of scratches on the surface of the object to be polished (particularly, silicon nitride and/or silicon oxide) after polishing is preferably less than 30, more preferably less than 20, further preferably less than 10, and particularly preferably less than 5. The lower limit of the number of scratches is 0. In the present specification, the scratch refers to a flaw having a depth of 10 nm or more and less than 100 nm, a width of 5 nm or more and less than 500 nm, and a length of 100 nm or more on the surface of the object to be polished. The number of scratches can be measured by the method described in Examples.

Although the embodiments of the present invention have been described in detail, this is illustrative and exemplary and not restrictive, and it is clear that the scope of the present invention should be interpreted by the appended claims.

The present invention includes the following aspects and embodiments.

1. A polishing composition containing: abrasive grains; and an alkylamine compound having at least one linear or branched alkyl group having 2 or more and 15 or less carbon atoms, in which a pH is less than 7, and a zeta potential of the abrasive grains in the polishing composition is negative;

2. The polishing composition described in above item 1., in which the alkylamine compound is a monoalkylamine compound having only one alkyl group;

3. The polishing composition described in above item 1. or 2., in which the number of carbon atoms of the alkyl group is 2 or more and 7 or less;

4. The polishing composition described in any one of above items 1. to 3., in which the alkylamine compound is at least one monoalkylamine compound selected from the group consisting of ethylamine, n-propylamine, n-butylamine, n-pentylamine, and n-hexylamine;

5. The polishing composition described in any one of above items 1. to 4., in which the abrasive grains are anionically modified colloidal silica;

6. The Polishing Composition Described in any One of Above Items 1. To 5., Further Containing a pH Adjusting Agent;

7. The polishing composition described in any one of above items 1. to 6., further containing an electrical conductivity adjusting agent;

8. The polishing composition described in any one of above items 1. to 7., further containing a dispersing medium;

9. The polishing composition described in any one of above items 1. to 8., in which the zeta potential of the abrasive grains in the polishing composition is −45 mV or more and −15 mV or less;

10. The polishing composition described in any one of above items 1. to 9., which is used for polishing an object to be polished containing a Low-k material and silicon nitride;

11. The polishing composition described in above item 10., in which the Low-k material is SiOC;

12. The polishing composition described in above item 10. or 11., in which a ratio of a polishing removal rate of the Low-k material to a polishing removal rate of the silicon nitride (the polishing removal rate of the Low-k material/the polishing removal rate of the silicon nitride) is 1.0 or more and 2.0 or less.

13. A polishing method comprising polishing an object to be polished containing a Low-k material and silicon nitride by using the polishing composition described in any one of above items 1. to 12.;

14. A method for producing a semiconductor substrate, including polishing a semiconductor substrate containing a Low-k material and silicon nitride by the polishing method described in above item 13;

15. The polishing composition described in any one of above items 1. to 9., which is used for polishing an object to be polished containing silicon oxide and silicon nitride;

16. The polishing composition described in above item 15., in which a ratio of a polishing removal rate of the silicon nitride to a polishing removal rate of the silicon oxide (the polishing removal rate of the silicon nitride/the polishing removal rate of the silicon oxide) is 1.5 or more and 2.5 or less;

17. A polishing method comprising polishing an object to be polished containing silicon oxide and silicon nitride by using the polishing composition described in any one of above items 1. to 9. and 15. to 16.; and

18. A method for producing a semiconductor substrate, including polishing a semiconductor substrate containing silicon oxide and silicon nitride by the polishing method described in above item 17.

### EXAMPLES

The present invention will be described in more detail with the following Examples and Comparative Examples. However, the technical scope of the present invention is not limited only to the following Examples. Unless otherwise specified, “%” and “part(s)” mean “% by mass” and “part(s) by mass” respectively. In the following Examples, unless otherwise specified, the operation was performed under the conditions of room temperature ((20° C. or higher and 25° C. or lower))/relative humidity of 40% RH or more and 50% RH or less. Each physical property was measured as follows.

### <Average Secondary Particle Size of Abrasive Grains>

The average secondary particle size of the abrasive grains was measured as a volume average particle size (volume-based arithmetic average diameter; Mv) by a dynamic light scattering particle size and particle size distribution apparatus UPA-UT151 (manufactured by NIKKISO CO., LTD.).

### <Zeta Potential of Abrasive Grains>

The zeta potential of the abrasive grains in the polishing composition was measured using a zeta potential measuring apparatus (instrument name “ELS-Z2”) manufactured by Otsuka Electronics Co., Ltd.

### <pH of Polishing Composition>

The pH of the polishing composition was measured by a pH meter (Model No.: LAQUA manufactured by HORIBA, Ltd.).

### <Electrical Conductivity of Polishing Composition>

The electrical conductivity (EC) of the polishing composition was measured by a tabletop-type electrical conductivity meter (Model No.: DS-71 LAQUA (registered trademark) manufactured by HORIBA, Ltd.).

### <Sulfonic Acid-Modified Colloidal Silica>

### Production Example 1

Sulfonic acid-modified colloidal silica as abrasive grains was obtained according to the following procedure.

### (Step of Preparing Raw Material Colloidal Silica Dispersion (Unmodified Silica Particles))

In a flask, 4080 g of methanol, 610 g of water, and 168 g of a 29% by mass aqueous ammonia solution were mixed, the liquid temperature was maintained at 20° C., and a mixed solution of 135 g of methanol and 508 g of tetramethoxysilane (TMOS) was added dropwise thereto for a dropwise addition time of 25 minutes. Thereafter, the resultant mixture was subjected to heat concentrated water replacement under a condition of pH 7 or more, and 1000 g of silica sol having a solid content concentration of 19.5% by mass was obtained (average secondary particle size: 34 nm).

### (Surface Modification Step)

Subsequently, to 1000 g of the silica sol (195 g in terms of silica solid content) obtained above, 2.4 g of 3-mercaptopropyl trimethoxysilane (MPS, silane coupling agent, product name: KBM-803, manufactured by Shin-Etsu Chemical Co., Ltd.) (silane coupling agent concentration with respect to the total mass of silica solid content: 1.2% by mass) separately mixed with 4.8 g of methanol was added dropwise at a flow rate of 1 mL/min. Thereafter, the mixture was heated and stirred at 90° C. for 1 hour.

Next, for cooling, the reaction solution was left to stand still overnight, 0.0686 g (3 mol with respect to 1 mol of the silane coupling agent) of 30% by mass hydrogen peroxide water was added thereto, and the mixture was heated again to 90° C. and stirred for 1 hour. Thereafter, the mixture was cooled to room temperature (25° C.) to obtain sulfonic acid-modified colloidal silica.

### Example 1

### <Preparation of Polishing Composition>

The sulfonic acid-modified colloidal silica (average secondary particle size: 34 nm) as the abrasive grains obtained in Production Example 1 was added to water as the dispersing medium so as to have a final concentration of 2% by mass. n-Hexylamine (manufactured by FUJIFILM Wako Pure Chemical Corporation) was further added so as to have a final concentration of 0.1% by mass, and stirred and mixed (stirring temperature: 25° C., stirring time: 20 minutes). The pH of the polishing composition was adjusted to 2.5 using nitric acid to complete the polishing composition.

### Example 2

A polishing composition was prepared in the same manner as in Example 1, except that the pH of the polishing composition was adjusted to 4.0.

### Example 3

A polishing composition was prepared in the same manner as in Example 1, except that ethylamine (manufactured by Tokyo Chemical Industry Co., Ltd.) was used instead of n-hexylamine.

### Example 4

A polishing composition was prepared in the same manner as in Example 1, except that n-butylamine (manufactured by FUJIFILM Wako Pure Chemical Corporation) was used instead of n-hexylamine.

### Example 5

A polishing composition was prepared in the same manner as in Example 1, except that n-heptylamine (manufactured by FUJIFILM Wako Pure Chemical Corporation) was used instead of n-hexylamine.

### Example 6

A polishing composition was prepared in the same manner as in Example 1, except that n-octylamine (manufactured by FUJIFILM Wako Pure Chemical Corporation) was used instead of n-hexylamine.

### Example 7

A polishing composition was prepared in the same manner as in Example 1, except that n-dodecylamine (manufactured by FUJIFILM Wako Pure Chemical Corporation) was used instead of n-hexylamine.

### Comparative Example 1

A polishing composition was prepared in the same manner as in Example 1, except that n-hexylamine was not used.

### Comparative Example 2

A polishing composition was prepared in the same manner as in Example 1, except that methylamine (manufactured by FUJIFILM Wako Pure Chemical Corporation) was used instead of n-hexylamine.

### Comparative Example 3

A polishing composition was prepared in the same manner as in Example 1, except that stearylamine (n-octadecylamine, manufactured by FUJIFILM Wako Pure Chemical Corporation) was used instead of n-hexylamine.

### Comparative Example 4

A polishing composition was prepared in the same manner as in Example 1, except that the pH of the polishing composition was adjusted to 7.0.

### [Evaluation]

### (Evaluation of Polishing Removal Rate of Polishing Compositions of Examples 1 to 7 and Comparative Examples 1 to 4)

The surface of each object to be polished was polished under the following conditions using each polishing composition of Examples 1 to 7 and Comparative Examples 1 to 4. As the object to be polished, the following (1) and (2) were prepared.

(1) Silicon nitride film (Si₃N₄ film): silicon wafer on which a silicon nitride film having a thickness of 2000 Å was formed on the surface (200 mm, blanket wafer)

(2) 200 mm wafer (SiOC film, manufactured by Advantec Co., Ltd., product name: BD 5kA Blanket).

Each of the prepared substrates was polished using the polishing composition of each of Examples 1 to 7 and Comparative Examples 1 to 4 under the following polishing conditions, and the polishing removal rate was measured.

### (Polishing Apparatus and Polishing Conditions)

Polishing apparatus: CMP single side polishing apparatus for 200 mm manufactured by Applied Materials Inc., Mirra
Polishing pad: Hard polyurethane pad IC1010 manufactured by Nitta DuPont Co., Ltd.
Polishing pressure: 2.0 psi (1 psi=6894.76 Pa)
Number of revolutions of polishing table: 87 rpm
Number of revolutions of head (carrier): 83 rpm
Supply of polishing composition: flow-through
Supply amount of polishing composition: 200 mL/min
Polishing time: 60 seconds.

### (Calculation of Polishing Removal Rate)

For each object to be polished, the thickness before and after polishing was determined with an optical film thickness measuring instrument (ASET-f5x: manufactured by KLA-Tencor Corporation). The film thickness was determined by an optical film thickness measuring instrument (ASET-f5x: manufactured by KLA-Tencor Corporation).

Polishing removal rate [Å/min]=(Film thickness [Å]before polishing−Film thickness [Å]after polishing)/Polishing time [min] [Mathematical Formula 1]

### (Selection Ratio A)

The selection ratio A was determined by dividing the polishing removal rate of the SiOC film obtained above by the polishing removal rate of the silicon nitride film (Si₃N₄ film). The selection ratio A is preferably 1.0 or more and 2.0 or less. The selection ratio A shown in the following Table 1 is a value obtained by rounding off to the first decimal place.

### (Scratch Evaluation of Polishing Compositions of Examples 1 to 7 and Comparative Examples 1 to 4)

The number of scratches on the surface of the object to be polished after polishing using the polishing compositions of Examples 1 to 7 and Comparative Examples 1 to 4 was evaluated. Specifically, using a wafer inspection apparatus “Surfscan (registered trademark) SP2” manufactured by KLA-Tencor Corporation, the number of scratches was measured by measuring the coordinates of the entire surface of the silicon nitride film (provided that, the outer periphery of 10 mm is excluded) and observing all the measured coordinates with Review-SEM (RS-6000, Hitachi High-Tech Co., Ltd.). Flaws having a depth of 10 nm or more and less than 100 nm, a width of 5 nm or more and less than 500 nm, and a length of 100 nm or more on the surface of the polished object to be polished were counted as scratches, and the number of scratches was evaluated according to the following evaluation criteria. It is preferable that the number of scratches is smaller.

### <Evaluation Criteria>

5: The number of scratches is less than 5.
4: The number of scratches is 5 or more and less than 10.
3: The number of scratches is 10 or more and less than 20.
2: The number of scratches is 20 or more and less than 30.
1: The number of scratches is 30 or more.

The configurations and evaluation results of the polishing compositions of Examples 1 to 7 and Comparative Examples 1 to 4 are shown in Table 1 below. “−” in Table 1 indicates that the relevant agent is not used.

TABLE 1

| | Abrasive grains | | | | | | | | | | | |
|---|---|---|---|---|---|---|---|---|---|---|---|---|
| | | Average | | Alkylamine compound | | | | | Evaluation | | | |
| | Concen- | secondary | | | Concen- | | | | Polishing | | | |
| | tration | particle | Zeta | | tration | Polishing composition | | | removal rate | | Selection | |
| | (% by | size | potential | | (% by | pH adjusting | | EC | (Å/min) | | ratio A | |
| | mass) | (nm) | (mV) | Type | mass) | agent | pH | (mS/cm) | SiOC | Si₃N₄ | SiOC/Si₃N₄ | Scratch |
| Example 1 | 2 | 34 | −35 | n-Hexylamine | 0.1 | Nitric acid | 2.5 | 2 | 650 | 387 | 1.7 | 5 |
| Example 2 | 2 | 34 | −35 | n-Hexylamine | 0.1 | Nitric acid | 4.0 | 2 | 579 | 365 | 1.6 | 5 |
| Example 3 | 2 | 34 | −40 | Ethylamine | 0.1 | Nitric acid | 2.5 | 2 | 398 | 412 | 1.0 | 5 |
| Example 4 | 2 | 34 | −40 | n-Butylamine | 0.1 | Nitric acid | 2.5 | 2 | 489 | 401 | 1.2 | 5 |
| Example 5 | 2 | 34 | −35 | n-Heptylamine | 0.1 | Nitric acid | 2.5 | 2 | 676 | 373 | 1.8 | 4 |
| Example 6 | 2 | 34 | −32 | n-Octylamine | 0.1 | Nitric acid | 2.5 | 2 | 683 | 356 | 1.9 | 3 |
| Example 7 | 2 | 34 | −28 | n-Dodecylamine | 0.1 | Nitric acid | 2.5 | 2 | 685 | 355 | 1.9 | 2 |
| Comparative | 2 | 34 | −45 | — | — | Nitric acid | 2.5 | 2 | 210 | 418 | 0.5 | 5 |
| Example 1 | | | | | | | | | | | | |
| Comparative | 2 | 34 | −45 | Methylamine | 0.1 | Nitric acid | 2.5 | 2 | 219 | 411 | 0.5 | 5 |
| Example 2 | | | | | | | | | | | | |
| Comparative | 2 | 34 | −15 | Stearylamine | 0.1 | Nitric acid | 2.5 | 2 | 719 | 189 | 3.8 | 1 |
| Example 3 | | | | (n-octadecylamine) | | | | | | | | |
| Comparative | 2 | 34 | −35 | n-Hexylamine | 0.1 | Nitric acid | 7.0 | 2 | 57 | 98 | 0.6 | 4 |
| Example 4 | | | | | | | | | | | | |

As is apparent from Table 1 above, it was found that when the polishing compositions of Examples were used, both the polishing removal rates of SiOC being the Low-k material and silicon nitride were 300 Å/min or more, and a high polishing removal rate was obtained. The ratio of the polishing removal rate of SiOC to the polishing removal rate of silicon nitride (selection ratio A) was 1.0 or more and 2.0 or less, and it was found that an appropriate selection ratio was obtained. On the other hand, in the case of using the polishing compositions of Comparative Examples, the polishing removal rate of any one of SiOC and silicon nitride was low, and the selection ratio A was not an appropriate value (1.0 or more and 2.0 or less).

In the case of using the polishing compositions of Examples, scratches on the surface of the object to be polished after polishing could be reduced. In the case of using the polishing composition of Comparative Example 3, scratches on the surface of the object to be polished after polishing increased.

Table 1 above shows results obtained by separately polishing an object to be polished having a Low-k material (SiOC) and an object to be polished having silicon nitride. However, even when the object to be polished having both the Low-k material and silicon nitride is polished, it is estimated that the same results of the polishing removal rate, the selection ratio, and scratches as those in Table 1 above can be obtained.

### Example 8

### <Sulfonic Acid-Modified Colloidal Silica>

### Production Example 2

Sulfonic acid-modified colloidal silica as abrasive grains was obtained according to the following procedure.

### (Step of Preparing Raw Material Colloidal Silica Dispersion (Unmodified Silica Particles))

In a flask, 4080 g of methanol, 610 g of water, and 168 g of a 29% by mass aqueous ammonia solution were mixed, the liquid temperature was maintained at 20° C., and a mixed solution of 135 g of methanol and 508 g of tetramethoxysilane (TMOS) was added dropwise thereto for a dropwise addition time of 25 minutes. Thereafter, the resultant mixture was subjected to heat concentrated water replacement under a condition of pH 7 or more, and 1000 g of silica sol having a solid content concentration of 19.5% by mass was obtained (average secondary particle size: 68 nm).

### (Surface Modification Step)

Subsequently, to 1000 g of the silica sol (195 g in terms of silica solid content) obtained above, 2.4 g of 3-mercaptopropyl trimethoxysilane (MPS, silane coupling agent, product name: KBM-803, manufactured by Shin-Etsu Chemical Co., Ltd.) (silane coupling agent concentration with respect to the total mass of silica solid content: 1.2% by mass) separately mixed with 4.8 g of methanol was added dropwise at a flow rate of 1 mL/min. Thereafter, the mixture was heated and stirred at 90° C. for 1 hour.

Next, for cooling, the reaction solution was left to stand still overnight, 0.0686 g (3 mol with respect to 1 mol of the silane coupling agent) of 30% by mass hydrogen peroxide water was added thereto, and the mixture was heated again to 90° C. and stirred for 1 hour. Thereafter, the mixture was cooled to room temperature (25° C.) to obtain sulfonic acid-modified colloidal silica.

### <Preparation of Polishing Composition>

The sulfonic acid-modified colloidal silica (average secondary particle size: 68 nm) as the abrasive grains obtained in Production Example 2 was added to water as the dispersing medium so as to have a final concentration of 2% by mass. n-Hexylamine (manufactured by FUJIFILM Wako Pure Chemical Corporation) was further added so as to have a final concentration of 0.01% by mass, and ammonium sulfate (manufactured by FUJIFILM Wako Pure Chemical Corporation) was added so as to have a final concentration of 0.6% by mass, followed by stirring and mixing (stirring temperature: 25° C., stirring time: 20 minutes). The pH of the polishing composition was adjusted to 2.5 using nitric acid to complete the polishing composition.

### Example 9

A polishing composition was prepared in the same manner as in Example 8, except that the pH of the polishing composition was adjusted to 4.0.

### Example 10

A polishing composition was prepared in the same manner as in Example 8, except that ethylamine (manufactured by Tokyo Chemical Industry Co., Ltd.) was used instead of n-hexylamine.

### Example 11

A polishing composition was prepared in the same manner as in Example 8, except that n-butylamine (manufactured by FUJIFILM Wako Pure Chemical Corporation) was used instead of n-hexylamine.

### Example 12

A polishing composition was prepared in the same manner as in Example 8, except that n-heptylamine (manufactured by FUJIFILM Wako Pure Chemical Corporation) was used instead of n-hexylamine.

### Example 13

A polishing composition was prepared in the same manner as in Example 8, except that n-octylamine (manufactured by FUJIFILM Wako Pure Chemical Corporation) was used instead of n-hexylamine.

### Example 14

A polishing composition was prepared in the same manner as in Example 8, except that n-dodecylamine (manufactured by FUJIFILM Wako Pure Chemical Corporation) was used instead of n-hexylamine.

### Comparative Example 5

A polishing composition was prepared in the same manner as in Example 8, except that n-hexylamine and ammonium sulfate were not used.

### Comparative Example 6

A polishing composition was prepared in the same manner as in Example 8, except that stearylamine (n-octadecylamine, manufactured by FUJIFILM Wako Pure Chemical Corporation) was used instead of n-hexylamine.

### Comparative Example 7

A polishing composition was prepared in the same manner as in Example 8, except that the pH of the polishing composition was adjusted to 7.0.

### (Evaluation of Polishing Removal Rate of Polishing Compositions of Examples 8 to 14 and Comparative Examples 5 to 7)

The surface of each object to be polished was polished under the following conditions using each polishing composition of Examples 8 to 14 and Comparative Examples 5 to 7. As the object to be polished, the following (1) and (2) were prepared.
(1) Silicon nitride film (Si₃N₄ film): silicon wafer on which a silicon nitride film having a thickness of 2000 Å was formed on the surface (200 mm, blanket wafer)
(2) Silicon oxide film (SiO: film): silicon wafer on which a silicon oxide film (TEOS type silicon oxide film produced using tetraethyl orthosilicate as precursor) having a thickness of 10000 Å was formed on the surface (200 mm, blanket wafer).

Each of the prepared substrates was polished using the polishing composition obtained above under the following polishing conditions, and the polishing removal rate was measured.

### (Polishing Apparatus and Polishing Conditions)

Polishing apparatus: CMP single side polishing apparatus for 200 mm manufactured by Applied Materials Inc., Mirra
Polishing pad: Hard polyurethane pad IC1010 manufactured by Nitta DuPont Co., Ltd.
Polishing pressure: 3.0 psi (1 psi=6894.76 Pa)
Number of revolutions of polishing table: 87 rpm
Number of revolutions of head (carrier): 83 rpm
Supply of polishing composition: flow-through
Supply amount of polishing composition: 200 mL/min
Polishing time: 60 seconds.

The calculation of the polishing removal rate was performed in the same manner as in the case of the polishing compositions of Examples 1 to 7 and Comparative Examples 1 to 4.

### (Selection Ratio B)

The selection ratio B was determined by dividing the polishing removal rate of the silicon nitride film (Si₃N₄ film) obtained above by the polishing removal rate of the silicon oxide film (SiO: film). The selection ratio B is preferably 1.5 or more and 2.5 or less. The selection ratio B shown in the following Table 2 is a value obtained by rounding off to the first decimal place.

### (Scratch Evaluation of Polishing Compositions of Examples 8 to 14 and Comparative Examples 5 to 7)

The scratches on the surface of the object to be polished after polishing using the polishing compositions of Examples 8 to 14 and Comparative Examples 5 to 7 were evaluated. Specifically, using a wafer inspection apparatus “Surfscan (registered trademark) SP2” manufactured by KLA-Tencor Corporation, the number of scratches was measured by measuring the coordinates of the entire surface of the silicon oxide film (provided that, the outer periphery of 10 mm is excluded) and observing all the measured coordinates with Review-SEM (RS-6000, Hitachi High-Tech Co., Ltd.). Flaws having a depth of 10 nm or more and less than 100 nm, a width of 5 nm or more and less than 500 nm, and a length of 100 nm or more on the surface of the polished object to be polished were counted as scratches, and the number of scratches was evaluated according to the following evaluation criteria. It is preferable that the number of scratches is smaller.

### <Evaluation Criteria>

5: The number of scratches is less than 5.
4: The number of scratches is 5 or more and less than 10.
3: The number of scratches is 10 or more and less than 20.
2: The number of scratches is 20 or more and less than 30.
1: The number of scratches is 30 or more.

The configurations and evaluation results of the polishing compositions of Examples 8 to 14 and Comparative Examples 5 to 7 are shown in Table 2 below. “−” in Table 2 indicates that the relevant agent is not used.

TABLE 2

| | | | | | | Electrical | |
|---|---|---|---|---|---|---|---|
| | Abrasive grains | | | | | conductivity | |
| | | Average | | Alkylamine compound | | adjusting agent | |
| | Concen- | secondary | | | Concen- | | Concen- |
| | tration | particle | Zeta | | tration | | tration |
| | (% by | size | potential | | (% by | | (% by |
| | mass) | (nm) | (mV) | Type | mass) | Type | mass) |
| Example 8 | 2 | 68 | −20 | n-Hexylamine | 0.01 | Ammonium | 0.6 |
| | | | | | | sulfate | |
| Example 9 | 2 | 68 | −24 | n-Hexylamine | 0.01 | Ammonium | 0.6 |
| | | | | | | sulfate | |
| Example 10 | 2 | 68 | −28 | Ethylamine | 0.01 | Ammonium | 0.6 |
| | | | | | | sulfate | |
| Example 11 | 2 | 68 | −28 | n-Butylamine | 0.01 | Ammonium | 0.6 |
| | | | | | | sulfate | |
| Example 12 | 2 | 68 | −20 | n-Heptylamine | 0.01 | Ammonium | 0.6 |
| | | | | | | sulfate | |
| Example 13 | 2 | 68 | −18 | n-Octylamine | 0.01 | Ammonium | 0.6 |
| | | | | | | sulfate | |
| Example 14 | 2 | 68 | −14 | n-Dodecylamine | 0.01 | Ammonium | 0.6 |
| | | | | | | sulfate | |
| Comparative | 2 | 68 | −35 | — | — | — | — |
| Example 5 | | | | | | | |
| Comparative | 2 | 68 | −8 | Stearylamine | 0.01 | Ammonium | 0.6 |
| Example 6 | | | | (n-octadecylamine) | | sulfate | |
| Comparative | 2 | 68 | −30 | n-Hexylamine | 0.01 | Ammonium | 0.6 |
| Example 7 | | | | | | sulfate | |

| | | | | Evaluation | | | |
|---|---|---|---|---|---|---|---|
| | | | | Polishing | | | |
| | Polishing composition | | | removal rate | | Selection | |
| | pH adjusting | | EC | (Å/min) | | ratio B | |
| | agent type | pH | (mS/cm) | Si₃N₄ | SiO₂ | Si₃N₄/SiO₂ | Scratch |
| Example 8 | Nitric acid | 2.5 | 7 | 669 | 356 | 1.9 | 5 |
| Example 9 | Nitric acid | 4.0 | 5 | 578 | 321 | 1.9 | 5 |
| Example 10 | Nitric acid | 2.5 | 7 | 676 | 362 | 1.9 | 5 |
| Example 11 | Nitric acid | 2.5 | 7 | 674 | 360 | 1.9 | 5 |
| Example 12 | Nitric acid | 2.5 | 7 | 656 | 345 | 1.9 | 4 |
| Example 13 | Nitric acid | 2.5 | 7 | 632 | 340 | 1.9 | 3 |
| Example 14 | Nitric acid | 2.5 | 7 | 544 | 289 | 1.9 | 2 |
| Comparative | Nitric acid | 2.5 | 7 | 687 | 366 | 1.9 | 1 |
| Example 5 | | | | | | | |
| Comparative | Nitric acid | 2.5 | 7 | 432 | 421 | 1.0 | 1 |
| Example 6 | | | | | | | |
| Comparative | Nitric acid | 7.0 | 5 | 132 | 298 | 0.4 | 4 |
| Example 7 | | | | | | | |

As is apparent from Table 2 above, it was found that when the polishing compositions of Examples 8 to 13 were used, both the polishing removal rates of silicon oxide and silicon nitride were 300 Å/min or more, and a high polishing removal rate was obtained. In the case of using the polishing compositions of Examples 8 to 14, the ratio of the polishing removal rate of silicon nitride to the polishing removal rate of silicon oxide (selection ratio B) was 1.5 or more and 2.5 or less, and it was found that an appropriate selection ratio was obtained, and scratches on the surface of the object to be polished after polishing were reduced. On the other hand, in the case of using the polishing compositions of Comparative Examples 5 and 6, scratches on the surface of the object to be polished after polishing increased. In the case of using the polishing compositions of Comparative Examples 6 and 7, the selection ratio B was not an appropriate value (1.5 or more and 2.5 or less).

Table 2 above shows results obtained by separately polishing an object to be polished having silicon oxide and an object to be polished having silicon nitride. However, even when the object to be polished having both silicon oxide and silicon nitride is polished, it is estimated that the same results of the polishing removal rate, the selection ratio, and scratches as those in Table 2 above can be obtained.

What is claimed is:

1. A polishing composition comprising:
abrasive grains; and
an alkylamine compound having at least one linear or branched alkyl group having 2 or more and 15 or less carbon atoms,
wherein a pH is less than 7, and
a zeta potential of the abrasive grains in the polishing composition is negative.

2. The polishing composition according to claim 1, wherein the alkylamine compound is a monoalkylamine compound having only one alkyl group.

3. The polishing composition according to claim 1, wherein the number of carbon atoms of the alkyl group is 2 or more and 7 or less.

4. The polishing composition according to claim 1, wherein the alkylamine compound is at least one monoalkylamine compound selected from the group consisting of ethylamine, n-propylamine, n-butylamine, n-pentylamine, and n-hexylamine.

5. The polishing composition according to claim 1, wherein the abrasive grains are anionically modified colloidal silica.

6. The polishing composition according to claim 1, further comprising a pH adjusting agent.

7. The polishing composition according to claim 1, further comprising an electrical conductivity adjusting agent.

8. The polishing composition according to claim 1, further comprising a dispersing medium.

9. The polishing composition according to claim 1, wherein the zeta potential of the abrasive grains in the polishing composition is −45 mV or more and −15 mV or less.

10. The polishing composition according to claim 1, which is used for polishing an object to be polished containing a Low-k material and silicon nitride.

11. The polishing composition according to claim 10, wherein the Low-k material is SiOC.

12. The polishing composition according to claim 10, wherein a ratio of a polishing removal rate of the Low-k material to a polishing removal rate of the silicon nitride (the polishing removal rate of the Low-k material/the polishing removal rate of the silicon nitride) is 1.0 or more and 2.0 or less.

13. A polishing method comprising polishing an object to be polished containing a Low-k material and silicon nitride by using the polishing composition according to claim 1.

14. A method for producing a semiconductor substrate, comprising polishing a semiconductor substrate containing a Low-k material and silicon nitride by the polishing method according to claim 13.

15. The polishing composition according to claim 1, which is used for polishing an object to be polished containing silicon oxide and silicon nitride.

16. The polishing composition according to claim 15, wherein a ratio of a polishing removal rate of the silicon nitride to a polishing removal rate of the silicon oxide (the polishing removal rate of the silicon nitride/the polishing removal rate of the silicon oxide) is 1.5 or more and 2.5 or less.

17. A polishing method comprising polishing an object to be polished containing silicon oxide and silicon nitride by using the polishing composition according to claim 1.

18. A method for producing a semiconductor substrate, comprising polishing a semiconductor substrate containing silicon oxide and silicon nitride by the polishing method according to claim 17.
